(19) United States
(12) Patent Application Publication
(10) Pub. No.: US 2026/0305435 A1
(43) Pub. Date: Oct. 1, 2026

(54) METHOD FOR MANUFACTURING SEMICONDUCTOR DEVICE

(71) Applicant: Resonac Corporation, Minato-ku, Tokyo (JP)

(72) Inventors: Yuki IMAZU, Tokyo (JP); Masaya TOBA, Tokyo (JP); Kazue HIRANO, Tokyo (JP); Kei TOGASAKI, Tokyo (JP)

(21) Appl. No.: 19/477,790

(22) PCT Filed: Dec. 8, 2023
(86) PCT No.: PCT/JP2023/044107

§ 371 Date: Oct. 23, 2025

(51) Int. Cl. H10W 72/00; G03F 7/16; H10W 70/05; H10W 74/01

(52) U.S. Cl. CPC H10W 72/01255; G03F 7/16; H10W 70/093; H10W 72/01204; H10W 74/019

(57) ABSTRACT

Disclosed is a method for producing an interposer using an encapsulation resin. In this method, a mask M having an exposure pattern is disposed above a resist layer 30 formed on a resist layer 20, and the resist layer 20 and the resist layer 30 are collectively exposed. The exposed resist layers 20 and 30 are collectively developed to obtain an opening pattern P. A metal pillar 40 is formed in the opening pattern P with a metal plating solution. In this method, an opening 31 formed in the outer resist layer 30 has a diameter or a width R2 larger than a diameter or a width R1 of an opening 21 formed in the inner resist layer 20. This arrangement facilitates permeation of the metal plating solution from the opening 31 toward the opening 21, thereby resulting in formation of the metal pillar 40 sufficient in height.

### TECHNICAL FIELD

The present disclosure relates to a method for manufacturing a semiconductor device. The present disclosure specifically relates to a method for manufacturing a semiconductor device for efficiently manufacturing, at a low cost, a semiconductor device having a high demand for high-speed transmission.

### BACKGROUND ART

For the purpose of high-speed transmission by a semiconductor package, a method has been proposed in which semiconductor chips different in performance are mounted together on a single package. In this packaging method, in order to enable high-speed transmission and miniaturization, a technology for high-density interconnection between chips has become important (for example, see Non-Patent Literature 1).

In order to achieve high-speed transmission and miniaturization of a semiconductor package, a semiconductor package that increases density by combination of materials different in physical property has been proposed. Particularly, in the fan-out wafer level packaging (FO-WLP), in order to parallelly mount semiconductor chips, a fine wiring layer is required for conduction between the semiconductor chips at high density (for example, see Non-Patent Literature 2). In addition, many technologies such as 2.5D packaging have been developed in which adjacent semiconductor chips are densely connected to each other through fine wiring and package substrates incorporating the semiconductor chips are longitudinally stacked, thereby achieving miniaturization and high-speed transmission of semiconductor devices. The 2.5D packaging is a technology for forming a relay substrate called a silicon interposer between semiconductor chips and a wiring substrate. In this technology, while the semiconductor chips disposed on the silicon interposer are finely connected to each other, the upper semiconductor chips and a lower wiring substrate can be mutually connected through a through-silicon via (TSV) formed in the silicon interposer.

### CITATION LIST

### Patent Literature

Patent Literature 1: Japanese Unexamined Patent Publication No. 2004-006773
Patent Literature 2: Japanese Unexamined Patent Publication No. 2016-213238

### Non Patent Literature

Non Patent Literature 1: Die Embedded Challenges for EMIB Advanced Packaging Technology, 2021 IEEE 71st Electronic Components and Technology Conference (ECTC), 2021
Non Patent Literature 2: System on Integrated Chips (SoIC™) for System for 3D Heterogeneous Integration, 2019 IEEE 69th Electronic Components and Technology Conference (ECTC), 2019

### SUMMARY OF INVENTION

### Technical Problem

With an increase in size of the silicon interposer applied to the 2.5D package, a warp in the entire substrate due to a difference in thermal expansion coefficient between the silicon interposer and the wiring substrate has increased. For this reason, a package form by a technique using other than the silicon interposer has attracted attention. As an example, a package form (chip-embedded interposer) including an encapsulation with a semiconductor chip embedded therein is applied as an interposer instead of a silicon wafer has been studied. In this chip-embedded interposer, upper semiconductor chips are finely connected to each other through a microconnection chip embedded in the encapsulation and a redistribution layer (RDL) that is formed using a photosensitive insulating material and formed on an upper portion of the interposer substrate, and the upper semiconductor chips and the lower wiring substrate are connected through a through interpose via (TIV) formed in the encapsulation. In this connection method, because the encapsulation that is a resin material is applied as a relay substrate, a difference in thermal expansion coefficient between the chip-embedded interposer and the substrate can be reduced, and low cost can be achieved.

As a method for forming the TIV, the following method is considered. A semi-additive process (SAP) is applied to form, by electrolytic plating, a columnar metal wiring (metal pillar) on a carrier substrate with a temporary fixing material layer formed on a substrate such as glass. At this time, because the metal pillar to be formed needs to be higher than the thickness of the fine connection chip to be embedded in the encapsulation, it is necessary to form a thick resist layer and to perform electrolytic via-filling plating on the via-shaped pattern formed through exposure and development steps. However, because the aspect ratio of the via-shaped pattern formed in the thick resist layer is large, a plating solution hardly enters inside the via at the time of electrolytic plating, and there is a concern about a deterioration in in-plane yield of electrolytic plating. According to the study by the present inventors, the reason why the electrolytic plating solution hardly enters inside the via is considered to be low wettability of the resist layer to the electrolytic plating solution. Therefore, resulting from the intensive study and focus on the opening on the side where the plating solution enters by the present inventors, the present inventors have conceived that the entering of the plating solution is enhanced by changing the size of the opening. In addition, the present inventors have further studied and considered that another resist layer having high wettability to the electrolytic plating solution is layered onto a base resist layer and both resist layers are collectively patterned that lead to expectation of improvement in in-plane yield of electrolytic plating while maintaining productivity.

An object of the present disclosure is to provide a method for manufacturing a semiconductor device in which a metal pillar sufficient in height can be formed.

### Solution to Problem

[1] The present disclosure relates to, as an aspect, a method for manufacturing a semiconductor device. This method for manufacturing the semiconductor device includes forming a first resist layer on a support substrate, forming a second resist layer on the first resist layer, disposing a mask having an exposure pattern above the second resist layer to collectively expose the first resist layer and the second resist layer, developing the exposed first resist layer and the exposed second resist layer, forming a metal pillar, with a metal plating solution, in an opening pattern formed in the developed first resist layer and the developed second resist layer, and removing the first resist layer and the second resist layer. In this method for manufacturing the semiconductor device, the diameter or width of a second opening in the opening pattern formed in the second resist layer is larger than the diameter or width of a first opening in the opening pattern formed in the first resist layer.

In this method for manufacturing the semiconductor device, the diameter or width of the second opening of the second resist layer is larger than the diameter or width of the first opening of the first resist layer. With this arrangement, in formation of the metal pillar with the metal plating solution, the metal plating solution easily permeates from the second opening toward the first opening. Therefore, according to this manufacturing method, the metal pillar sufficient in height can be formed. Further, in this manufacturing method, patterning is performed collectively while using the two types of resist layers, and thus provided can be a method for manufacturing a semiconductor device with a higher yield while maintaining the production speed.
[2] In the method for manufacturing the semiconductor device according to [1] described above, the second resist layer may have a contact angle of 400 or less to a liquid. In this case, the second resist layer is easily wetted with the metal plating solution. As a result, in formation of the metal pillar with the metal plating solution, the metal plating solution easily permeates from the second opening toward the first opening. Therefore, according to this manufacturing method, the metal pillar sufficient in height can be formed. Note that the liquid referred to herein is water.
[3] In the method for manufacturing the semiconductor device according to [2] described above, the second resist layer preferably has a contact angle of 300 or less to the liquid. In this case, the second resist layer is further easily wetted with the metal plating solution. As a result, in formation of the metal pillar with the metal plating solution, the metal plating solution further easily permeates from the second opening toward the first opening. Therefore, according to this manufacturing method, the metal pillar sufficient in height can be formed.
[4] The method for manufacturing the semiconductor device according to any one of [1] to [3] described above may further include performing a treatment that improves wettability on the second resist layer. In this case, the second resist layer is reliably easily wetted with the metal plating solution. As a result, in formation of the metal pillar with the metal plating solution, the metal plating solution reliably easily permeates from the second opening toward the first opening. Therefore, according to this manufacturing method, the metal pillar sufficient in height can be formed.
[5] In the method for manufacturing the semiconductor device according to [4] described above, the performing the treatment that improves wettability preferably includes irradiating the second resist layer with at least either oxygen plasma or ultraviolet light. In this case, the wettability of the second resist layer to the metal plating solution can be reliably improved, and the permeation of the metal plating solution from the second opening formed in the second resist layer can be enhanced by a simple means.
[6] In the method for manufacturing the semiconductor device according to any one of [1] to [5] described above, the second resist layer may be formed so as to make a thickness of the second resist layer thinner than a thickness of the first resist layer. In this case, in collective development of the resist layers, the second resist layer can be prevented from being peeled. Therefore, the metal pillar can be reliably formed with the second resist layer kept remaining.
[7] In the method for manufacturing the semiconductor device according to [6] described above, the second resist layer may be formed so as to make the thickness of the second resist layer half or less than half the thickness of the first resist layer. In this case, in development of the resist layers, the second resist layer can be reliably prevented from being peeled. Therefore, the metal pillar can be reliably formed with the second resist layer kept remaining.
[8] In the method for manufacturing the semiconductor device according to any one of [1] to [7] described above, the first resist layer preferably has a thickness of 15 μm or more, and the second resist layer preferably has a thickness of 15 μm or less. In this case, in development of the resist layers, the second resist layer can be reliably prevented from being peeled. Therefore, the metal pillar can be reliably formed with the second resist layer kept remaining.
[9] In the method for manufacturing the semiconductor device according to any one of [1] to [8] described above, an absorption coefficient of a second resist material for use in the forming the second resist layer may be lower than an absorption coefficient of a first resist material for use in the forming the first resist layer. In this case, even if the second resist layer is layered on the first resist layer, the first resist layer can be reliably developed to form the opening pattern (first opening). Therefore, the metal pillar can be reliably formed.
[10] In the method for manufacturing the semiconductor device according to [9] described above, the absorption coefficient of the second resist material is preferably less than 0.018 mol·L⁻¹·μm⁻¹, and the absorption coefficient of the first resist material is preferably 0.018 mol·L⁻¹·μm⁻¹ or more. In this case, even if the second resist layer is layered on the first resist layer, the first resist layer can be reliably developed to form the opening pattern (first opening). Therefore, the metal pillar can be reliably formed.
[11] In the method for manufacturing the semiconductor device according to [1] to [10] described above, the forming the first resist layer may include forming the first resist layer on a seed layer on the support substrate, and the forming the metal pillar may include forming the metal pillar on the seed layer. This method for manufacturing the semiconductor device may further include removing, in the seed layer, a seed layer portion out of a region where the metal pillar is formed. In this case, the metal pillar can be easily formed using the seed layer, with the metal plating solution.
[12] The method for manufacturing the semiconductor device according to [1] to [11] described above may further include forming an encapsulation layer on the support substrate, on which the metal pillar is formed, such that the encapsulation layer covers the metal pillar. In this case, the metal pillar can be provided in the encapsulation layer.
[13] The method for manufacturing the semiconductor device according to [12] described above may further include performing at least either grinding or polishing on the encapsulation layer to expose a leading end of the metal pillar from the encapsulation layer.
[14] The method for manufacturing the semiconductor device according to [12] or [13] described above may further include mounting a first semiconductor chip on the support substrate on which the metal pillar is formed, and the forming the encapsulation layer may include encapsulating the first semiconductor chip together with the metal pillar. As a result, a connection chip can be easily formed in the encapsulation layer.
[15] The method for manufacturing the semiconductor device according to any one of [1] to [14] described above may further include connecting a second semiconductor chip to a first end of the metal pillar and connecting a wiring substrate to a second end of the metal pillar. In this case, a semiconductor device including an interposer formed of a resin material can be obtained. Further, the expansion coefficient between the interposer as a relay substrate and the wiring substrate is brought close, whereby the semiconductor device in which the occurrence of warp is prevented can be obtained.

### Advantageous Effects of Invention

According to the present disclosure, a metal pillar sufficient in height can be formed.

### BRIEF DESCRIPTION OF DRAWINGS

FIG. 1 (a) to (c) of FIG. 1 are schematic sectional views sequentially illustrating a method for manufacturing a semiconductor device according to an embodiment.

FIG. 2 (a) to (c) of FIG. 2 are schematic sectional views sequentially illustrating the method for manufacturing the semiconductor device according to the embodiment.

FIG. 3 (a) and (b) of FIG. 3 are schematic sectional views sequentially illustrating the method for manufacturing the semiconductor device according to the embodiment.

FIG. 4 (a) to (d) of FIG. 4 are schematic sectional views sequentially illustrating the method for manufacturing the semiconductor device according to the embodiment.

FIG. 5 is a schematic sectional view illustrating an exemplary semiconductor device.

FIG. 6 is a view illustrating the contact angle of liquid to a resist layer.

FIG. 7 (a) to (d) of FIG. 7 are schematic sectional views illustrating a method for manufacturing a semiconductor device according to a modification.

### DESCRIPTION OF EMBODIMENTS

Hereinafter, some embodiments of the present disclosure will be described in detail with reference to the drawings as necessary. In the following description, the same or corresponding portions are denoted by the same reference signs, and redundant description is not given. Further, unless otherwise specified, positional relationships such as up, down, left, and right are based on the positional relationships illustrated in the drawings. The use of the terms such as “left”, “right”, “front”, “back”, “up”, “down”, “above”, and “below” in the description of the present specification and claims is intended for description, and thus is not necessarily meant to indicate the permanent relative positions thereof. Furthermore, the dimensional ratios in the drawings are not limited to the illustrated ratios.

In the present specification, the term “layer” includes a structure having a shape partially formed in addition to a structure having a shape formed on the entire surface when observed as a plan view. In the present specification, the term “step” includes not only an independent step but also a step that cannot be clearly distinguished from other steps as long as an intended action of the step is achieved. A numerical range using “to” indicates a range including numerical values described before and after “to” as a minimum value and a maximum value.

In the present specification, a (meth)acrylate means an acrylate or a methacrylate corresponding thereto. The same applies to other similar expressions such as a (meth)acryloyl group and a (meth)acrylic copolymer. The components and materials exemplified in the present specification may be used singly or in combination of two or more types thereof unless otherwise specified.

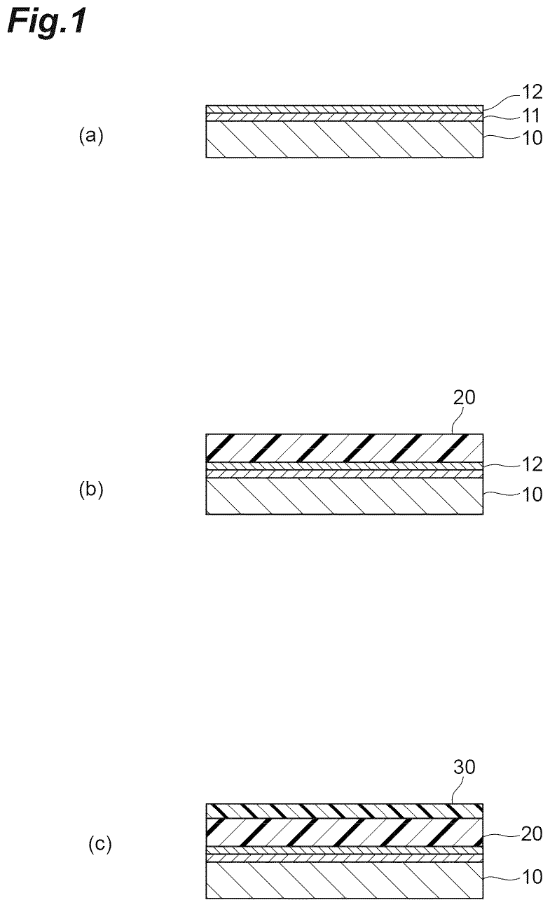

With reference to FIGS. 1 to 4, a method for manufacturing a semiconductor device according to an embodiment of the present disclosure will be described. FIGS. 1 to 4 are schematic sectional views sequentially illustrating a method for manufacturing a semiconductor device (relay substrate) according to an embodiment. The method for manufacturing the semiconductor device according to the present embodiment is particularly suitable in a form in which high density and high productivity are required, and is suitable in a package form in which an interposer or a fan-out technology for mixedly mounting different types of chips is required. More specifically, the method for manufacturing the semiconductor device according to the present embodiment is suitable in a package form having a space of 100 μm or less between the pins (metal pillars) (e.g., 20 to 100 μm in a finer case) and 500 pins or more (e.g., 1000 to 10000 pins in a finer case). However, the present invention is not limited to the above-described aspects.

The semiconductor device according to the present embodiment can be manufactured, for example, through Steps (a) to (m) below. Some steps may be omitted or repeated.
(a) A step of preparing a support substrate.
(b) A step of forming a first resist layer on the support substrate.
(c) A step of forming a second resist layer on the first resist layer.
(d) A step of collectively exposing the first resist layer and the second resist layer.
(e) A step of developing the exposed first resist layer and second resist layer.
(f) A step of forming a metal pillar in an opening pattern formed in the first resist layer and the second resist layer.
(g) A step of removing the first resist layer and the second resist layer.
(h) A step of removing, in the seed layer, a seed layer portion out of the region where the metal pillar is formed.
(i) A step of mounting a semiconductor chip on the support substrate on which the metal pillar is formed.
(j) A step of forming an encapsulation layer on the support substrate such that the encapsulation layer covers the metal pillar and the semiconductor chip.
(k) A step of performing at least either grinding or polishing on the encapsulation layer.
(l) A step of removing the support substrate.
(m) A step of connecting a second semiconductor chip to the first end of the metal pillar and connecting a wiring substrate to the second end of the metal pillar.
   [Step (a)]

In Step (a), as illustrated in (a) of FIG. 1, a support substrate 10 is prepared. A temporarily fixing layer 11 and a seed layer 12 are formed on the support substrate 10. The support substrate 10 is, for example, a silicon plate, a glass plate, an SUS plate, a substrate containing glass cloth, or an encapsulation resin containing a semiconductor chip, and is preferably a substrate having high rigidity. The thickness of the support substrate 10 is, for example, 0.2 mm to 2.0 mm. The thickness of 0.2 mm or more of the support substrate 10 results in improvement of the handleability. The thickness of 2.0 mm or less of the support substrate 10 results in reduction of the material cost. The planar shape of the support substrate 10 may be a wafer shape or a panel shape. The size of the support substrate 10 is not particularly limited, but a wafer having a diameter of 200 mm, a diameter of 300 mm, or a diameter of 450 mm, or a rectangular panel having one side with 300 to 700 mm is preferably used. The temporarily fixing layer 11 is a resin layer for temporarily fixing the support substrate 10 and the seed layer 12 to each other, and is a layer that is peeled off in removal of the support substrate 10. In Step (a), the temporarily fixing layer 11 is formed on the support substrate 10, and then the seed layer 12 is deposited by a PVD method or a CVD method. The seed layer 12 is a part serving as a seed for metal plating in formation of metal pillar and is formed of, for example, copper.

[Step (b)]

In Step (b), as illustrated in (b) of FIG. 1, a resist layer 20 (first resist layer) is formed on the surface of the seed layer 12 formed on the support substrate 10. The method for forming the resist layer 20 is not particularly limited, but a resist film can be formed with a film forming apparatus such as a vacuum laminator, a roll laminator, or a pressure bonding machine. The thickness of the resist layer 20 is, for example, 15 μm or more, and is 20 μm as an example.

[Step (c)]

In Step (c), as illustrated in (c) of FIG. 1, a resist layer 30 (second resist layer) is formed on the resist layer 20 formed on the support substrate 10. The resist layer 30 is preferably formed to be thinner than the resist layer 20, and the thickness of the resist layer 30 may be half or less than half the thickness of the resist layer 20. The thickness of the resist layer 30 is, for example, 15 μm or less, and is 10 μm as an example.

### (Resist Material)

Here, the resist material used in Step (c) and Step (d) will be described. The resist material for forming the resist layer 20 and the resist layer 30 is not particularly limited, but is, for example, a photosensitive resin composition containing a binder polymer, a photopolymerizable compound having an ethylenically unsaturated bond, and a photopolymerization initiator. The resist material is, for example, a negative resist material.

The binder polymer may be, for example, a copolymer containing benzyl (meth)acrylate or a derivative thereof, styrene or a styrene derivative, a (meth)acrylic acid alkyl ester, and (meth)acrylic acid as monomer units.

Specific examples of the benzyl (meth)acrylate derivative constituting the binder polymer include 4-methylbenzyl (meth)acrylate, 4-ethylbenzyl (meth)acrylate, 4-tert-butylbenzyl (meth)acrylate, 4-methoxybenzyl (meth)acrylate, 4-ethoxybenzyl (meth)acrylate, 4-hydroxylbenzyl (meth)acrylate, and 4-chlorobenzyl (meth)acrylate.

Specific examples of the styrene derivative constituting the binder polymer include vinyltoluene, p-methyl styrene, and p-chlorostyrene.

A proportion of the monomer unit derived from benzyl (meth)acrylate or a derivative thereof in the binder polymer may be 50 to 80 mass %, 50 to 75 mass %, 50 to 70 mass %, or 50 to 65 mass % based on the mass of the binder polymer. A proportion of the monomer unit derived from styrene or a styrene derivative in the binder polymer may be 5 to 40 mass % or 5 to 35 mass % based on the mass of the binder polymer. A proportion of the monomer unit derived from a (meth)acrylic acid alkyl ester in the binder polymer may be 1 to 20 mass %, 1 to 15 mass %, 1 to 10 mass %, or 1 to 5 mass % based on the mass of the binder polymer. A proportion of the monomer unit derived from a (meth)acrylic acid in the binder polymer may be 5 to 30 mass %, 5 to 25 mass %, or 10 to 25 mass % based on the mass of the binder polymer.

The weight average molecular weight (Mw) of the binder polymer may be 20000 to 150000, 30000 to 100000, 40000 to 80000, or 40000 to 60000. The weight average molecular weight as used herein means a corresponding value in terms of standard polystyrene as determined by gel permeation chromatography (GPC).

An acid value (mgKOH/g) of the binder polymer may be 13 to 78, 39 to 65, or 52 to 62. The acid value as used herein means the amount (mg) of potassium hydroxide in the electrolytic plating solution required for neutralization of 1 g of the binder polymer.

Specific examples of the photopolymerizable compound having an ethylenically unsaturated bond include bisphenol A-based (meth)acrylate compounds, electrolytic plating solution-added bisphenol A-based (meth)acrylate compounds, polyalkylene glycol (meth)acrylates, urethane monomers, pentaerythritol (meth)acrylates, and trimethylolpropane (meth)acrylates. These may be used singly, or two or more thereof may be used in combination. Such a bisphenol A-based di(meth)acrylate compound may be, for example, a compound represented by the following general formula (1).

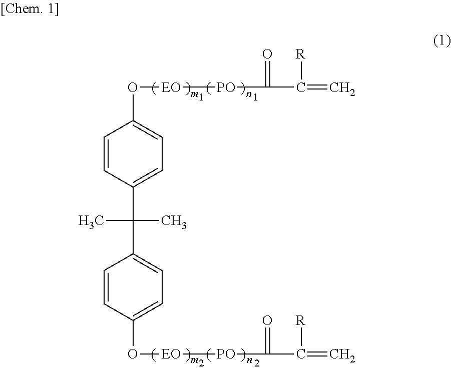

In Formula (1), Rs each independently represent an electrolytic plating solution elemental atom or a methyl group. EO and PO represent an oxyethylene group and an oxypropylene group, respectively. m₁, m₂, n₁, and n₂ each independently represent 0 to 40, m₁+m₂ represents 1 to 40, and n₁+n₂ represents 0 to 20. Either EO or PO may be present on a phenolic electrolytic plating solution acid group side. m₁, m₂, n₁, and n₂ each represent the number of EOs or POs. A compound in which m₁+m₂ is 5 or less on average and a compound in which m₁+m₂ is 6 to 40 on average may be combined.

The polyalkylene glycol (meth)acrylate may be a compound represented by the following formula (2). As the photopolymerizable compound having an ethylenically unsaturated bond, a bisphenol A-based di(meth)acrylate compound and a compound represented by the following formula (2) may be combined.

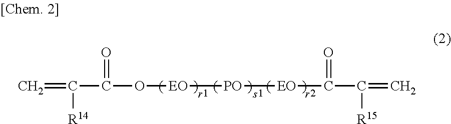

In Formula (2), R¹⁴ and R¹⁵ each independently represent an electrolytic plating solution neutral atom or a methyl group, EO and PO have the same meaning as described above, s¹ represents 1 to 30, r¹ and r² each represent 0 to 30, and r¹+r² represents 1 to 30. Examples of commercially available products of the compound represented by Formula (2) include vinyl compounds (trade name: FA-023M, manufactured by Resonac Corporation) in which R¹⁴ and R¹⁵ are methyl groups, r¹+r²=4 (average value), and s′=12 (average value).

Specific examples of the photopolymerization initiator include aromatic ketones such as benzophenone, N,N′-tetramethyl-4,4′-diaminobenzophenone (Michler's ketone), N,N′-tetraethyl-4,4′-diaminobenzophenone, 4-methoxy-4′-dimethylaminobenzophenone, 2-benzyl-2-dimethylamino-1-(4-morpholinophenyl)-butanone-1, and 2-methyl-1-[4-(methylthio)phenyl]-2 morpholino-propanone-1; quinones such as 2-ethylanthraquinone, phenanthrenequinone, 2-tert-butylanthraquinone, octamethylanthraquinone, 1,2-benzanthraquinone, 2,3-benzanthraquinone, 2-phenylanthraquinone, 2,3-diphenylanthraquinone, 1-chloroanthraquinone, 2-methylanthraquinone, 1,4-naphthoquinone, 9,10 phenanthraquinone, 2-methyl 1,4-naphthoquinone, and 2,3-dimethylanthraquinone; benzoin ether compounds such as benzoin methyl ether, benzoin ethyl ether, and benzoin phenyl ether, and benzoin compounds such as benzoin, methylbenzoin, and ethylbenzoin; benzyl derivatives such as benzyl dimethyl ketal, and 2,4,5-triarylimidazole dimers such as 2-(o-chlorophenyl)-4,5-diphenylimidazole dimer, 2-(o-chlorophenyl)-4,5-di(methoxyphenyl)imidazole dimer, 2-(o-fluorophenyl)-4,5-diphenylimidazole dimer, 2-(o-methoxyphenyl)-4,5-diphenylimidazole dimer, and 2-(p-methoxyphenyl)-4,5-diphenylimidazole dimer; acridine derivatives such as 9-phenylacridine and 1,7-bis(9,9′-acridinyl)heptane; N-phenylglycine; N-phenylglycine derivatives; and coumarin-based compounds. These are used singly, or two or more thereof are used in combination. The photopolymerization initiator may contain a 2,4,5-triarylimidazole dimer, particularly a 2-(O-chlorophenyl)-4,5-diphenylimidazole dimer.

The content of the binder polymer in the photosensitive resin composition may be 40 to 80 parts by mass, 45 to 75 parts by mass, or 50 to 70 parts by mass per 100 parts by mass of the total amount of the binder polymer and the photopolymerizable compound. The content of the photopolymerization initiator in the photosensitive resin composition may be 0.01 to 5 parts by mass, 0.1 to 4.5 parts by mass, or 1 to 4 parts by mass per 100 parts by mass of the total amount of the binder polymer and the photopolymerizable compound.

The photosensitive resin composition may contain other components as necessary. Examples of the other components include a photopolymerizable compound having a cationically polymerizable cyclic ether group, a cationic polymerization initiator, a sensitizer, a dye such as Malachite Green, photochromogenic agents such as tribromomethylphenyl sulfone and Leuco Crystal Violet, a thermal coloring inhibitor, a plasticizer such as p-toluenesulfonamide, a pigment, a filler, an antifoaming agent, a flame retardant, a stabilizer, an adhesion imparting agent, a leveling agent, a peeling accelerator, an antioxidant, a fragrance, an imaging agent, and a thermal crosslinking agent. The content of each of the other components may be about 0.01 to 20 parts by mass per 100 parts by mass of the total amount of the binder polymer and the photopolymerizable compound.

The total content of the binder polymer, the photopolymerizable compound, and the photopolymerization initiator in the photosensitive resin composition may be 90 to 100 mass % or 95 to 100 mass % to the total mass of components other than the solvent in the photosensitive resin composition.

Further, the resist material forming the resist layer 20 and the resist layer 30 is preferably a material having the following absorption coefficient. Specifically, the absorption coefficient of the resist material for use in formation of the resist layer 30 is preferably lower than the absorption coefficient of the resist material for use in formation of the resist layer 20. More specifically, the absorption coefficient of the resist material for use in formation of the resist layer 30 is preferably less than 0.018 mol·L⁻¹·μm⁻¹, and the absorption coefficient of the resist material for use information of the resist layer 20 is preferably 0.018 mol·L⁻¹·μm⁻¹, or more. As an example, the absorption coefficient of the resist material for use in formation of the resist layer 30 is 0.015 mol·L⁻¹·μm⁻¹, and the absorption coefficient of the resist material for use in formation of the resist layer 20 is 0.021 mol·L⁻¹·μm⁻¹. Note that the “absorption coefficient” referred to herein can be measured with, for example, an ultraviolet-visible spectrophotometer UV-2600 (manufactured by Shimadzu Corporation), and is an absorption coefficient at a wavelength of 365 nm. In this case, even if the resist layer 30 is layered on the resist layer 20, the lower resist layer 20 can be reliably developed to form an opening pattern in the development step to be described later.

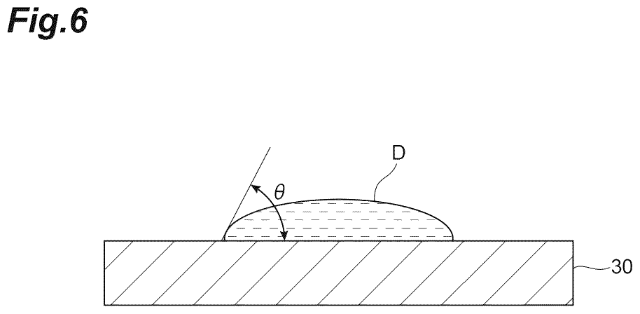

Further, the upper resist layer 30 preferably has a contact angle of 400 or less to water. The contact angle referred to herein is an index indicating the wettability of the constituent material of the resist layer 30 to liquid, and means a contact angle θ when water D is dropped on the resist layer 30 as illustrated in FIG. 6. The contact angle θ referred to herein is a contact angle to water but is 40° or less also in the case of a metal plating solution, from the viewpoint of measurement reliability. In the metal plating solution, for example, a copper plating solution, most of the constituent components are water, and the contact angle to the resist is equivalent to that to water. Therefore, the contact angle of the resist layer 30 to the metal plating solution can be handled as being approximate to the contact angle to water. When the contact angle θ is large, the wettability is low, indicating that the wettability is improved as the contact angle θ reduces. More specifically, the resist layer 30 preferably has a contact angle θ of 30° or less to water D (or the metal plating solution). When the contact angle θ is 30° or less, the electrolytic plating solution easily permeates inside the via-shaped pattern (in the opening) formed in the resist layer 30, and the yield of electrolytic plating is improved.

As a method for reducing the contact angle θ of the resist layer 30 to a liquid, for example, a predetermined surface treatment may be performed. The surface treatment method is not particularly limited, but, for example, immersion treatment with a cleaner liquid containing an acid component, plasma treatment using argon gas or oxygen gas, or UV modification are preferable. Note that the present inventors evaluated the contact angle θ of the resist layer 30 formed of a negative photosensitive dry film resist containing a binder polymer, a photopolymerizable compound having an ethylenically unsaturated bond, and a photopolymerization initiator. In this evaluation, as illustrated in FIG. 6, the resist layer 30 was formed of the negative photosensitive dry film resist, and the change in the contact angle θ between the case where a surface treatment was not performed and the case where a surface treatment was performed was evaluated. In this evaluation, the contact angle θ to water was evaluated as indicated in Table 1 below. As a result, the contact angle θ to water was 67.9° without performing a surface treatment, whereas the contact angle θ to water was successfully reduced as follows by performing various surface treatments. Among them, the surface treatment with oxygen plasma and the UV modification were more preferable. Note that the cleaner A was a treatment with a cleaner solution containing a nonionic surfactant, the cleaner B was a treatment with a cleaner solution containing an anionic surfactant, and the cleaner C was a treatment with a cleaner solution containing an acidic surfactant.

TABLE 1

| With or without surface treatment | |
|---|---|
| and types of surface treatment | Contact angle to water (°) |
| Without surface treatment | 67.9 |
| Oxygen plasma | 9.9 |
| UV modification | 29.2 |
| Cleaner A | 45.5 |
| Cleaner B | 56 |
| Cleaner C | 39.7 |

When a meta pillar to be described later was formed after performing the surface treatment with oxygen plasma and the UV modification described above, voids were prevented from entering the plating solution, and plating defects were reliably reduced.

[Step (d)]

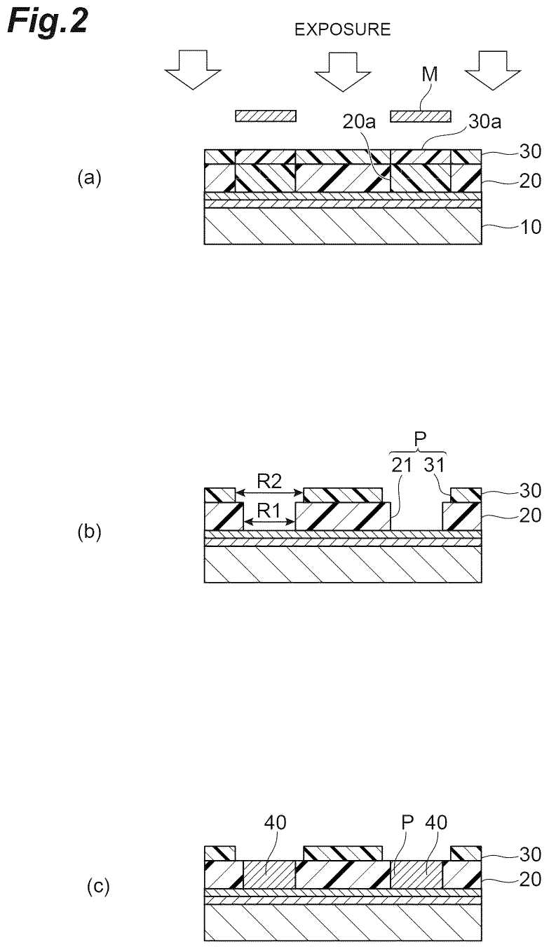

Returning to the steps, the description will be continued. In Step (d), as illustrated in (a) of FIG. 2, a mask M having a predetermined exposure pattern is disposed above the resist layer 30, and the resist layer 20 and the resist layer 30 on the support substrate 10 are collectively exposed. The exposure method is not particularly limited, but active rays such as ultraviolet rays, visible rays, or radiation are irradiated through the mask M. After the exposure, post exposure bake (PEB) may be performed as necessary. The temperature at the post exposure bake is preferably 70° C. to 140° C., and the duration of the post exposure bake is preferably 1 minute to 5 minutes.

[Step (e)]

In Step (e), as illustrated in (b) of FIG. 2, the exposed resist layer 20 and the exposed resist layer 30 are developed with a developer. As an example, in a case where the resist material is a negative type, in this step, the unexposed portion 20a of the exposed resist layer 20 and the unexposed portion 30a of the exposed resist layer 30 on the support substrate 10 (see (a) of FIG. 2) are developed with the developer, so that the resist layer 20 and the resist layer 30 are patterned. In the opening 21 (first opening) of the resist layer 20 and the opening 31 (second opening) of the resist layer 30 formed by the above-described exposure and development, the diameter or width R2 of the outer opening 31 is formed to be larger than the diameter or width R1 of the inner opening 21. That is, the relationship of R2≥R1 is established. By establishing R2≥R1 in this manner, the entire opening has a mortar shape, and the electrolytic plating solution is likely to be immersed in water. As an example, R1=30 μm and R2=35 μm are preferable.

As the developer used for development, in the case of alkali development, for example, an alkali aqueous solution such as sodium hydroxide, potassium hydroxide, sodium silicate, ammonia, ethylamine, diethylamine, triethylamine, triethanolamine, or tetramethylammonium hydroxide (TMAH) is suitably used. The base concentration of these aqueous solutions is preferably 0.1 to 10 mass %. Further, an alcohol or a surfactant may be added to the developer to use. These can be blended in a range of preferably 0.01 to 10 parts by mass, more preferably 0.1 to 5 parts by mass per 100 parts by mass of the developer.

[Step (f)]

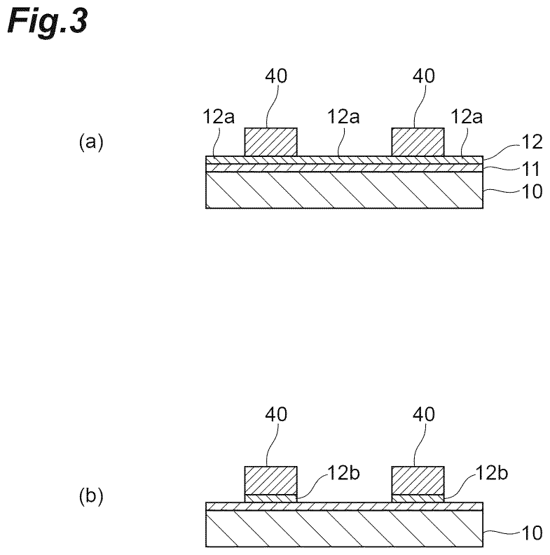

In Step (f), as illustrated in (c) of FIG. 2, a metal pillar 40 is formed with a metal plating solution in the opening pattern P formed in the developed resist layer 20 and resist layer 30. The opening pattern P is a via-shaped pattern. The metal type of the metal pillar 40 is not particularly limited, but copper is preferably used from the viewpoint of workability and versatility. Further, the method for electrolytic plating is not particularly limited, but from the viewpoint of the permeation efficiency of the electrolytic plating solution into the via-shaped pattern, it is preferable to apply jet-type electrolytic plating in which the plating solution is ejected perpendicularly to the plating surface of the plating target to stir the plating solution. Furthermore, from the viewpoint of stirring efficiency, paddle-stirring electrolytic plating in which a portion in front of the plating surface of the plating target is stirred with a paddle blade may be applied. In this manufacturing method, because the resist layer 20 and the resist layer 30 are layered and then patterning is collectively performed, the metal plating solution easily permeates inside the via-shaped pattern. Therefore, semiconductor device can be manufactured with a high yield as compared with the conventional process.

[Step (g)]In Step (g), as illustrated in (c) of FIG. 2 and (a) of FIG. 3, the resist layer 20 and the resist layer 30 that are kept remaining on the support substrate 10 after the formation of the metal pillar 40, are removed. The method for removing the resist is not particularly limited, but the resist is preferably removed with an alkaline peeling solution from the viewpoint of peelability.
[Step (h)]

In Step (h), as illustrated in (a) and (b) of FIG. 3, in the seed layer 12 that is kept remaining on the support substrate 10 after the formation of the metal pillar 40, a seed layer portion 12a out of the region where the metal pillar 40 is formed, is removed. A method for removing the seed layer portion 12a is not particularly limited, but is preferably a dip type, a spray type, or a paddle type. As a result, only an electrode portion 12b remains. The electrode portion 12b constitutes a part of a pillar electrode mainly including the metal pillar 40.

[Step (i)]

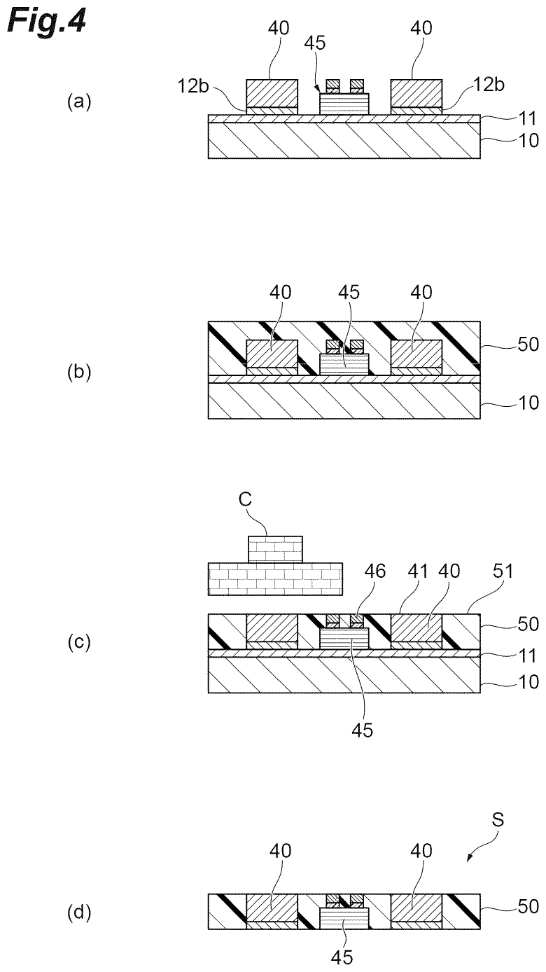

In Step (i), as illustrated in (a) of FIG. 4, a semiconductor chip 45 (first semiconductor chip) is mounted on the support substrate 10 on which the metal pillar 40 is formed. The semiconductor chip 45 is a connection semiconductor chip for connecting semiconductor chips different from each other. Note that metal wiring, an electrode pad, a connection bump, and a pillar may be formed on the support substrate 10 as well as the metal pillar 40 and the semiconductor chip 45.

[Step (j)]

In Step (j), as illustrated in (b) of FIG. 4, an encapsulation layer 50 is formed on the support substrate 10 such that the encapsulation layer 50 covers the metal pillar 40 and the semiconductor chip 45. In this step, encapsulating is performed by forming an encapsulation material such as an epoxy resin in a mold with a compression-type or transfer-type molding machine to form the encapsulation layer 50. The encapsulated-formed encapsulation body may be heated with an oven or a hot plate, for example. With metal wiring and others formed on the support substrate 10, the metal wiring and the others are also encapsulated together with the metal pillar 40 and the semiconductor chip 45.

[Step (k)]

In Step (k), as illustrated in (c) of FIG. 4, at least either grinding or polishing is performed on the encapsulation layer 50. In this step, the surface of the encapsulation layer 50 is exposed by grinding. This grinding is performed, for example, by a method for grinding with a grindstone rotating at a high speed. As a result of this grinding, the leading end 41 of the metal pillar 40 and a connection terminal 46 of the semiconductor chip 45 that are encapsulated in the encapsulation layer 50 are exposed from the surface 51 of the encapsulation layer 50.

In Step (k), polishing by a CMP method may be performed after grinding from the viewpoint of grinding variation. For example, a portion to be polished is polished while a polishing liquid (not illustrated) is supplied between the polishing pad C (polishing cloth) and the portion to be polished (encapsulation layer 50) on the support substrate 10. As the polishing liquid for CMP, various types of polishing liquids are known. The polishing liquid for CMP is classified according to the type of abrasive grains (polishing particles) contained, and examples of the abrasive grains include cerium oxide (ceria) particles, silicon oxide (silica) particles, aluminum oxide (alumina) particles, and organic resin particles. From the viewpoint of the polishing speed, for example, ceria-based particles are preferably applied as the abrasive grains.

[Step (l)]

In Step (l), as illustrated in (d) of FIG. 4, the support substrate 10 is removed. In order to remove the support substrate 10, the temporarily fixing layer 11 is subjected to a predetermined treatment for peeling (for example, heat treatment in the case of heat peeling), and the support substrate 10 is removed from the encapsulating body together with the temporarily fixing layer 11. As a result, a relay substrate S functioning as an interposer is obtained.

[Step (m)]

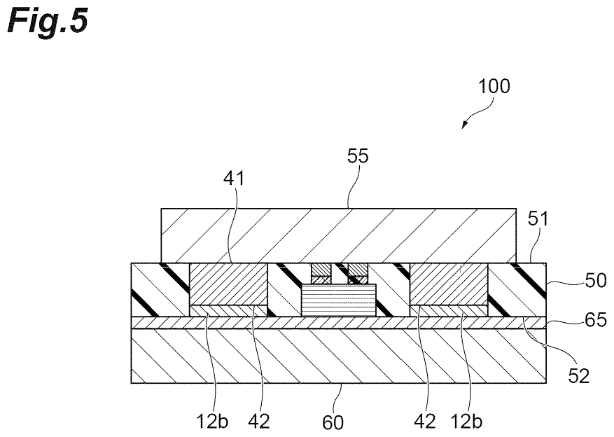

In Step (m), as illustrated in FIG. 5, a semiconductor chip 55 (second semiconductor chip) is mounted on the surface 51 of the encapsulation layer 50 of the relay substrate S, and a wiring substrate 60 is attached to the back face 52 of the encapsulation layer 50 of the relay substrate S. As a result, the leading end 41 (first end) of the metal pillar 40 is connected to the semiconductor chip 55, and the other end 42 (second end) of the metal pillar 40 is connected to the wiring substrate 60 through the electrode portion 12b. A rewiring layer 65 may or may not be provided between the relay substrate S and the semiconductor chip 55 and between the relay substrate S and the wiring substrate 60. Thus, a semiconductor device 100 is produced. Note that, in FIG. 5, the configuration of the semiconductor device 100 is simplified in order to facilitate the description, but the semiconductor device 100 may include a plurality of semiconductor chips 55 or mounting components. In addition, in the semiconductor device 100, such a semiconductor chip 55 may be further encapsulated.

As described above, according to the method for manufacturing the semiconductor device according to the present embodiment, the diameter or the width R2 of the opening 31 of the resist layer 30 is larger than the diameter or the width R1 of the opening 21 of the resist layer 20. Therefore, in formation of the metal pillar 40 with the metal plating solution, the metal plating solution easily permeates from the opening 31 toward the opening 21. Thus, according to this manufacturing method, the metal pillar 40 sufficient in height can be formed. In addition, in this manufacturing method, because the patterning is performed collectively while using two different types of resist layers, a method for manufacturing a semiconductor device with a higher yield while maintaining the production speed can be provided.

In the method for manufacturing the semiconductor device according to the present embodiment, the contact angle θ of the resist layer 30 to water may be 40° or less, and is preferably 30° or less. As a result, the resist layer 30 is easily wetted with the metal plating solution, and the metal plating solution easily permeates. Therefore, according to this manufacturing method, the metal pillar sufficient in height can be formed.

In the method for manufacturing the semiconductor device according to the present embodiment, a treatment for improving wettability may be performed on the resist layer 30. As a result, the resist layer 30 is reliably easily wetted with the metal plating solution, and the metal plating solution reliably easily permeates from the opening 31 toward the opening 21. Therefore, according to this manufacturing method, the metal pillar sufficient in height can be formed. Note that as such a wettability improvement treatment, irradiation is preferably performed with at least either oxygen plasma or ultraviolet light.

In the method for manufacturing the semiconductor device according to the present embodiment, the resist layer 30 is formed such that the thickness of the resist layer 30 is thinner than the thickness of the resist layer 20. As a result, peeling of the resist layer 30 can be prevented in the development of the resist layers. Therefore, the metal pillar 40 can be reliably formed with the resist layer 30 kept remaining. In this case, the resist layer 30 is preferably formed such that the thickness of the resist layer 30 is half or less than half the thickness of the resist layer 20. Further, the thickness of the resist layer 20 is preferably 15 μm or more, and the thickness of the resist layer 30 is preferably 15 μm or less.

In the method for manufacturing the semiconductor device according to the present embodiment, the light absorption coefficient of the resist material (second resist material) for use in the formation of the resist layer 30 may be lower than the light absorption coefficient of the resist material (first resist material) for use in the formation of the resist layer 20. In this case, even if the resist layer 30 is layered on the resist layer 20, the lower resist layer 20 can be reliably developed to form the opening 21. Therefore, the metal pillar 40 can be reliably formed. In this case, the absorption coefficient of the resist material of the resist layer 30 is preferably less than 0.018 mol·L⁻¹··m⁻¹, and the absorption coefficient of the resist material of the resist layer 20 is preferably 0.018 mol·L⁻¹·μm⁻¹ or more. As a result, the resist layer 20 can be more reliably developed to form the openings 21. Therefore, the metal pillar 40 can be reliably formed.

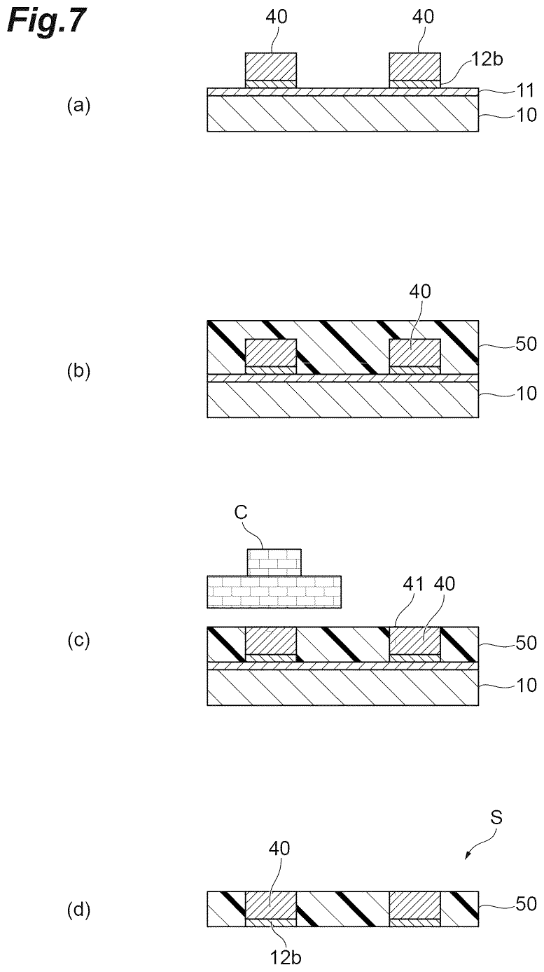

Although the method for manufacturing the semiconductor device according to the present embodiment has been described above, the method for manufacturing the semiconductor device according to the present invention is not limited to the above-described embodiment, and thus various modifications can be made. For example, as illustrated in (a) of FIG. 7, a metal pillar 40 may be provided without providing a semiconductor chip 45 on a support substrate 10. In this case, as illustrated in (b) of FIG. 7, an encapsulation layer 50 is formed on the support substrate 10 such that the encapsulation layer 50 covers the metal pillar 40. Then, as illustrated in (c) of FIG. 7, at least either grinding or polishing is performed on the encapsulation layer 50. Finally, as illustrated in (d) of FIG. 7, the support substrate 10 is removed from the encapsulation body. A semiconductor device 100 may be produced with such a relay substrate S1.

### REFERENCE SIGNS LIST

10 SUPPORT SUBSTRATE
12 SEED LAYER
12a SEED LAYER PORTION
20 RESIST LAYER (FIRST RESIST LAYER)
21 OPENING (FIRST OPENING)
30 RESIST LAYER (SECOND RESIST LAYER)
31 OPENING (SECOND OPENING)
40 METAL PILLAR
45 SEMICONDUCTOR CHIP (FIRST SEMICONDUCTOR CHIP)
50 ENCAPSULATION LAYER
55 SEMICONDUCTOR CHIP (SECOND SEMICONDUCTOR CHIP)
60 WIRING SUBSTRATE
100 SEMICONDUCTOR DEVICE

1. A method for manufacturing a semiconductor device, the method comprising:
forming a first resist layer on a support substrate;
forming a second resist layer on the first resist layer;
disposing a mask having an exposure pattern above the second resist layer to collectively expose the first resist layer and the second resist layer;
developing the exposed first resist layer and the exposed second resist layer;
forming a metal pillar, with a metal plating solution, in an opening pattern formed in the developed first resist layer and the developed second resist layer; and
removing the first resist layer and the second resist layer,
wherein the diameter or width of a second opening in the opening pattern formed in the second resist layer is larger than the diameter or width of a first opening in the opening pattern formed in the first resist layer.

2. The method for manufacturing the semiconductor device according to claim 1,
wherein the second resist layer has a contact angle of 40° or less to a liquid.

3. The method for manufacturing the semiconductor device according to claim 2,
wherein the second resist layer has a contact angle of 30° or less to the liquid.

4. The method for manufacturing the semiconductor device according to claim 1, further comprising
performing a treatment that improves wettability on the second opening formed in the second resist layer.

5. The method for manufacturing the semiconductor device according to claim 4,
wherein the performing the treatment that improves wettability includes irradiating the second opening formed in the second resist layer with at least either oxygen plasma or ultraviolet light.

6. The method for manufacturing the semiconductor device according to claim 1,
wherein the forming the second resist layer includes making a thickness of the second resist layer thinner than a thickness of the first resist layer.

7. The method for manufacturing the semiconductor device according to claim 6,
wherein the forming the second resist layer includes making the thickness of the second resist layer half or less than half the thickness of the first resist layer.

8. The method for manufacturing the semiconductor device according to claim 1,
wherein the first resist layer has a thickness of 15 μm or more, and the second resist layer has a thickness of 15 μm or less.

9. The method for manufacturing the semiconductor device according to claim 1,
wherein an absorption coefficient of a second resist material for use in the forming the second resist layer is lower than an absorption coefficient of a first resist material for use in the forming the first resist layer.

10. The method for manufacturing the semiconductor device according to claim 9,
wherein the absorption coefficient of the second resist material is less than 0.018 mol·L⁻¹·μm⁻¹, and the absorption coefficient of the first resist material is 0.018 mol·L⁻¹·μm⁻¹ or more.

11. The method for manufacturing the semiconductor device according to claim 1,
wherein the forming the first resist layer includes forming the first resist layer on the seed layer on the support substrate, and
the forming the metal pillar includes forming the metal pillar on the seed layer,
the method further comprising
removing, in a seed layer, a seed layer portion out of a region where the metal pillar is formed.

12. The method for manufacturing the semiconductor device according to claim 1, further comprising
forming an encapsulation layer on the support substrate, on which the metal pillar is formed, such that the encapsulation layer covers the metal pillar.

13. The method for manufacturing the semiconductor device according to claim 12, further comprising
performing at least either grinding or polishing on the encapsulation layer to expose a leading end of the metal pillar from the encapsulation layer.

14. The method for manufacturing the semiconductor device according to claim 12, further comprising
mounting a first semiconductor chip on the support substrate on which the metal pillar is formed,
wherein the forming the encapsulation layer includes encapsulating the first semiconductor chip together with the metal pillar.

15. The method for manufacturing the semiconductor device according to claim 1, further comprising
connecting a second semiconductor chip to a first end of the metal pillar and connecting a wiring substrate to a second end of the metal pillar.
